(19) United States
(12) Patent Application Publication
(10) Pub. No.: US 2013/0002873 A1
(43) Pub. Date: Jan. 3, 2013

(54) IMAGING SYSTEM FOR VEHICLE

(75) Inventor: Holger Hess, Aschaffenburg (DE)

(73) Assignee: MAGNA ELECTRONICS EUROPE GMBH & CO. KG, Sailauf-Eichenberg (DE)

(21) Appl. No.: 13/534,657

(22) Filed: Jun. 27, 2012

Related U.S. Application Data
(60) Provisional application No. 61/503,098, filed on Jun. 30, 2011.

(51) Int. Cl. H04N 7/18; H01L 27/146

(52) U.S. Cl. 348/148; 250/208.1; 348/E07.085

(57) ABSTRACT

An imaging or vision system for a vehicle includes an imaging sensor disposed at the vehicle and having an imaging array of photosensing pixels. A first optical element is disposed at a first portion of the imaging array and has a first focal length, and a second optical element is disposed at a second portion of the imaging array and has a second focal length. The first focal length is longer than the second focal length so that the first portion of the imaging array captures focused images of a more remote or distant scene than that of the second portion of the imaging array. The first portion of the imaging array may capture images of a scene occurring forwardly of the vehicle and the second portion of the imaging array may capture images of a surface of the vehicle windshield.

### CROSS REFERENCE TO RELATED APPLICATION

The present application claims the filing benefit of U.S. provisional application Ser. No, 61/503,098, filed Jun. 30, 2011, which is hereby incorporated herein by reference in its entirety.

### FIELD OF THE INVENTION

The present invention relates to imaging systems or vision systems for vehicles and, more particularly, to an imaging or vision system that includes at least one imaging device or camera for capturing images of a scene interior or exterior of the vehicle.

### BACKGROUND OF THE INVENTION

Use of imaging sensors in vehicle imaging systems is common and known. Examples of such known systems are described in U.S. Pat. Nos. 5,949,331; 5,670,935; and/or 5,550,677, which are hereby incorporated herein by reference in their entireties. When incorporating a camera into a vehicle, such as, for example, in an interior rearview mirror assembly for a forward viewing vision system, the space for any components or accessories is important and thus the packaging and package size are important features of the camera. In some vehicle applications, there may be two or more cameras for providing different fields of view (such as one camera facing generally forwardly in the forward direction of travel of the vehicle and one camera facing generally sidewardly towards a side region of the vehicle). Other sensing applications show combined projection areas of split optical systems having identical focal lenses, U.S. Pat. No. 6,617,564 suggests a vehicle moisture sensor, having a two lens system for projecting the same image (same focal lens) on two different areas of one image sensor.

### SUMMARY OF THE INVENTION

The present invention provides a vision system or imaging system for a vehicle that utilizes a dual lens configuration to capture two separate and distinct images on different imaging array portions, preferably onto different imaging portions of a single or common imaging array of photosensors. For example, one lens may be disposed at one portion of the single imaging array and may provide a longer focal length and another lens may be disposed at another portion of the single imaging array and may provide a shorter focal length. Optionally, the different imaging array portions may comprise separate and distinct imaging arrays, each with a respective lens for focusing the respective image onto that imaging array.

According to an aspect of the present invention, an imaging or vision system for a vehicle includes an imaging device or sensor or camera with a pair of lenses or lens assemblies or optical elements disposed at the imaging sensor. The imaging sensor comprises an imaging array of photosensing pixels. A first lens or optical element is disposed at a first portion or array of the imaging array and provides a first focal length and a second lens or optical element is disposed at a second portion or array of the imaging array and provides a second focal length. The first focal length is longer than the second focal length so that the first portion of the imaging array captures focused images of a more remote or distant scene than that of the second portion of the imaging array.

Optionally, the imaging sensor may be disposed at or in the vehicle so as to have a generally forward field of view in the forward direction of travel of the vehicle. For example, the imaging sensor may be disposed at or in an interior rearview mirror assembly of a vehicle and may have a generally forward field of view through the windshield of the vehicle. Optionally, the first portion of the imaging array may have a forward field of view through the windshield of the vehicle and the first lens or optical element may focus an image at the first portion of the imaging array that is representative of a scene occurring forwardly of the vehicle, such as several yards or meters ahead of the vehicle at or on the road on which the vehicle is traveling, such as for a headlamp control system or lane departure warning system of the vehicle, while the second portion of the imaging array may have a field of view at the vehicle windshield and the second lens or optical element may focus an image at the second portion of the imaging array that is representative of the windshield itself, such as for a rain sensing function or accessory of the vehicle.

Therefore, the present invention provides a dual function imaging sensor or imaging system that, with a single imaging array and associated circuitry, can provide separate and distinct images or image data via a dual lens system or assembly disposed at the imaging array of the imaging sensor for focusing different images onto the respective portions of the imaging array of the imaging sensor. The present invention thus provides enhanced imaging while limiting or reducing or minimizing the space requirements for the imaging sensor or camera.

These and other objects, advantages, purposes and features of the present invention will become apparent upon review of the following specification in conjunction with the drawings.

### BRIEF DESCRIPTION OF THE DRAWINGS

FIG. 1 is a plan view of a vehicle with a vision system and an imaging sensor or camera that provides two exterior fields of view in accordance with the present invention;

FIG. 2 is a schematic of an imaging sensor and lens assembly of the vision system of the present invention;

FIG. 3 is a schematic of the imaging sensor and array of the vision system of the present invention; and

FIG. 4 is an image showing the imaging provided by the vision system of the present invention.

### DESCRIPTION OF THE PREFERRED EMBODIMENTS

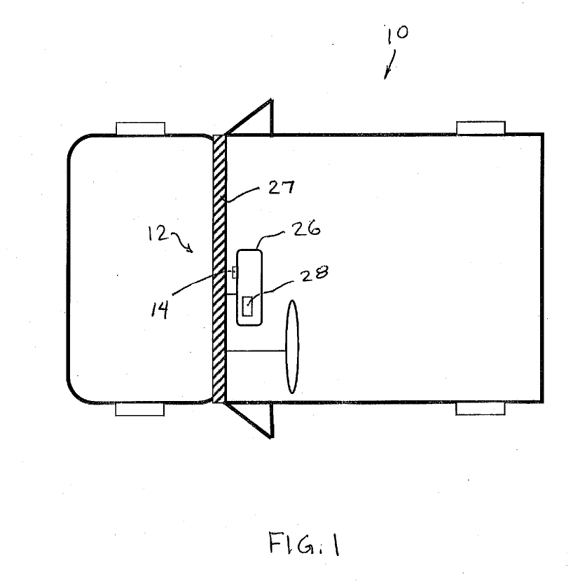

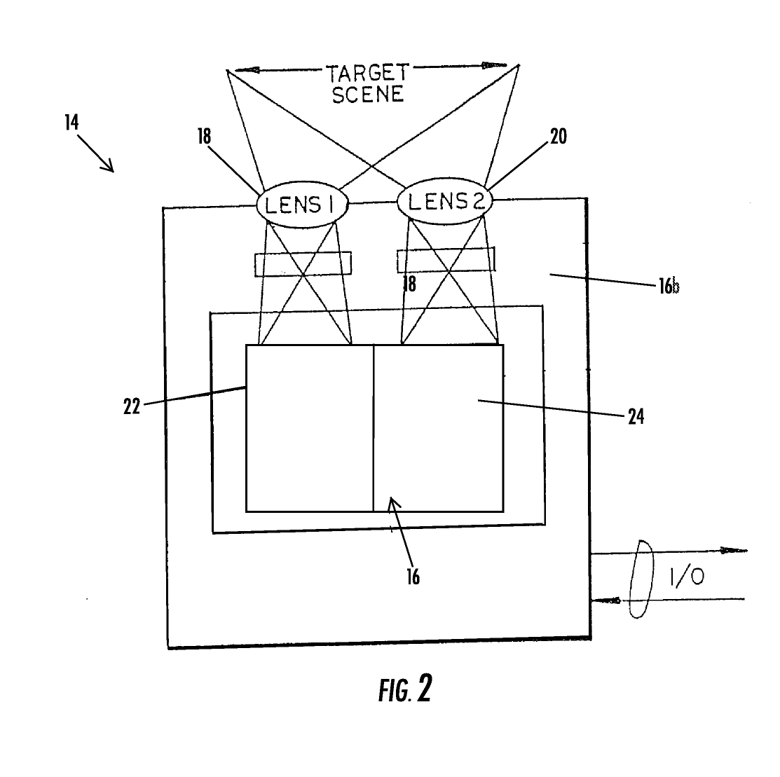

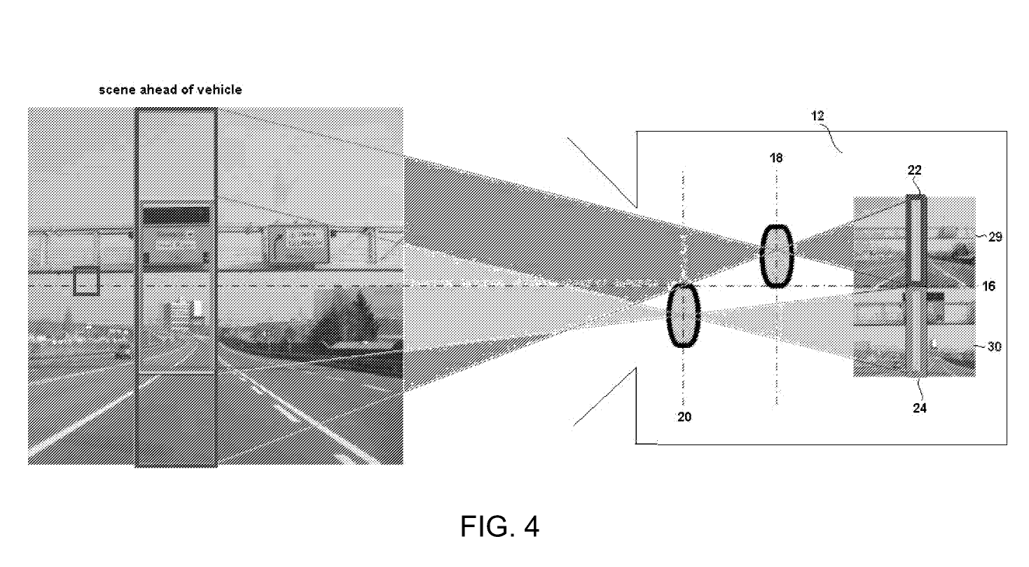

Referring now to the drawings and the illustrative embodiments depicted therein, a vehicle 10 includes an imaging system or vision system 12 that includes an imaging sensor or camera 14 which senses light from a scene forward of vehicle 10, with the imaging sensor 14 comprising an imaging array 16 of photosensing pixels 16a disposed on a common semiconductor substrate 16b and a pair of lenses or lens assemblies or optical elements 18, 20 disposed at respective portions 22, 24 of the imaging array 16 (FIGS. 1-3). The lens assemblies 18, 20 are configured with different characteristics so as to image or focus different images onto the respective portions 22, 24 of the imaging array 16, such that an image processor may process the image data captured by the different portions 22, 24 for different functions or applications, such as for a headlamp control function or adaptive cruise control and a rain sensing function or the like, as discussed below. As shown in FIG. 4, image projections 29, 30 are projected onto different image array portions 22, 24 of a scene forward of the camera, with the different image array portions 22, 24 capturing the images via different focal lengths. The imaging array portions may be commonly established on a common semiconductor substrate and/or may be spaced apart from one another to provide separate imaging arrays or imaging array portions.

Because there are times or vehicle applications where there is a need to have a vehicle camera or imaging sensor detect or “see” a substantial or far distance in front of the vehicle as the vehicle is traveling along the road (such as for detection of headlamps of approaching vehicles or detection of taillights of leading vehicles or detection of other vehicles on the road such as for an adaptive cruise control system or collision avoidance system or the like, or such as lane marker detection or sign or object detection forward of the vehicle) and for other applications there is a need for near imaging, such as for rain sensing at the vehicle windshield or the like. far or near (e.g., see w/s for rain sensing, see far for headlamp detection), there is a need to provide multiple sensing means for the vehicle, without adversely affecting the packaging or size requirements for the imaging system. Likewise, for some applications, there is a need or desire for a clearer focus at objects or scenes exterior of the vehicle, while other applications do not require or need such clarity in the captured images. Also, for some applications, there is a need or desire for a generally straight forward field of view in front of the vehicle, while other applications, there is a need or desire for a generally sideward field of view towards a side region of the vehicle or the like. Typically, for such different applications or different imaging systems or functions, two separate imaging devices or cameras may be utilized.

The present invention provides a single camera or imaging sensor that utilizes a dual lens system or split lens system to focus or image different images (such as a near image and a far image or such as a forward image and a sideward image or the like) onto respective portions (such as two halves) of the single imaging sensor. Each of the portions of the imaging sensor may be fully capable of full color imaging (such as via color filters, such as red, green and blue filters or the like, disposed at the pixels of each of the imaging array portions) or may be capable of black and white imaging or may be capable of red-clear-clear imaging such as is known in the art. The imaging array thus may comprise a typical black and white imaging array or color imaging array, with both sides having similar or the same pixel filtering arrangement and the like.

The lenses 18, 20 are disposed at the respective portions or halves 22, 24 of the imaging array 16 and may have different characteristics, such as different focal lengths, to provide the desired focusing and imaging for the respective imaging array portion. For example, a first lens 18 may provide a telephoto or longer focal length to provide imaging at imaging array portion 22 of far or distant objects ahead (or sideward) of the vehicle, while the second lens 20 may comprises a wider angle lens or shorter focal length (or even a macro lens for close up imaging) to provide imaging at imaging array portion 24 of nearer objects or the like ahead or sideward of the vehicle or imaging sensor. For example, the first imaging array portion 22 may capture images or image data for processing for a headlamp control system or lane departure warning system or sign recognition system or object detection system or the like, while the second imaging array portion 24 may capture images or image data of close-up objects, such as the interior and/or exterior surface of the vehicle windshield for moisture detection (such as rain sensing or fog sensing or condensation sensing or the like). Optionally, one or both of the lenses may comprise enhanced optics to provide clearer focusing of images onto the respective portion or portions of the imaging array, depending on the particular application of the respective portion or portions of the imaging array. For example, a first optical element may be used for detection of objects very far away from the subject vehicle, such as far ahead of the subject vehicle on or at the road on which the vehicle is travelling (where a higher spatial resolution may be desired) and a second optical element may be used for detection of objects in the nearer field, such as close to the subject vehicle (where a lower resolution may be desired or acceptable). For example, the first optical element and associated portion of the imaging array may function to capture images or image data for vehicle detection in the far field, while the second optical element and associated portion of the imaging array may function to capture images or image data for vehicle and road sign detection in the near field.

Each of the lenses 18, 20 may comprise any suitable lens or lens assembly or optical element, such as a single molded plastic lens banded to or in close contact with the respective portion 22, 24 of the photosensor imaging array 16, or such as any appropriate or suitable image focusing means such as conventional single component optics, holographic lens type optics, binary optics or a microlens or an adjustable focus single-optic or multi-optic lens or the like. Although referred to as a lens, such a lens may comprise a multiple lens system consisting of many individual lens elements or optic elements, and such lens elements or optic elements may comprise or include defractive optics, holographic optics, plastic optics, glass optics, spherical optics, aspherical optics and/or the like. Each lens 18, 20 is designed to focus a respective image of the forward scene within a field of view onto the respective portion 22, 24 of the imaging array 16. Although shown and described as having generally forward fields of view, the imaging sensor 14 and lenses 18, 20 may be disposed elsewhere in the vehicle or otherwise positioned in other than a forwardly facing direction so long as appropriate lenses or other optics are used to direct the light or image information from the targeted area or areas onto the portions 22, 24 of the photosensitive surface of the photosensor array 16.

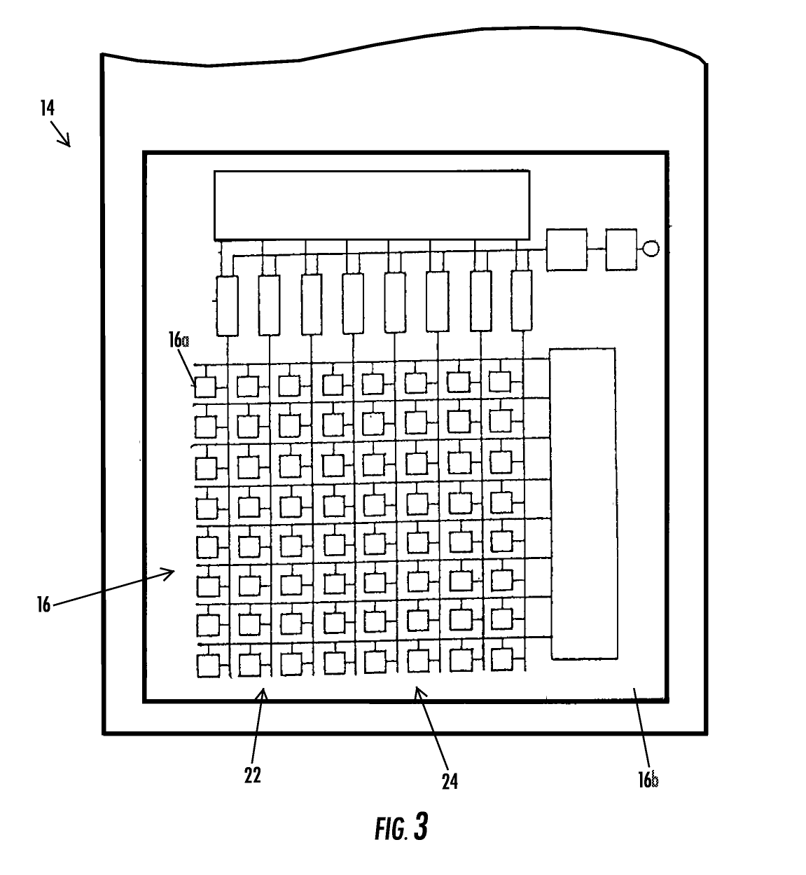

The imaging sensor 14 and its photosensor array 16 may comprise any suitable camera or sensing device, such as, for example, an array of a plurality of photosensor elements 16a arranged in 640 columns and 480 rows (a 640×480 Imaging array), with a respective lens focusing images onto respective portions of the array. In the embodiment illustrated in FIG. 3, the photosensor array 16 is shown as a 8×8 photosensor array for illustrative purposes only, and it is desirable to have a larger array (more pixels) for providing enhanced clarity of the captured images. The photosensor array 16 thus may comprise any appropriately sized array that is divisible into two or more imaging array portions with each imaging array portion being associated with a respective lens assembly or optic so as to have an appropriate field of view for capturing the desired images or image data for the respective vehicle application or function.

As shown in FIG. 3, the photosensor array 16 generally comprises a plurality of photosensor elements 16a arranged in a photosensor array having rows and columns. The logic and control circuit of the imaging sensor may function in any known manner, such as in the manner described in U.S. Pat. Nos. 5,550,677; 5,877,897; 6,498,620; 5,670,935; 5,796,094; and/or 6,396,397, and/or U.S. provisional applications, Ser. No. 61/648,744, filed May 18, 2012; Ser. No. 61/624,507, filed Apr. 16, 2012; Ser. No. 61/616,126, filed Mar. 27, 2012; Ser. No. 61/615,410, filed Mar. 26, 2012; Ser. No. 61/613,651, filed 2012; Ser. No. 61/607,229, filed Mar. 6, 2012; Ser. No. 61/605,409, filed Mar. 1, 2012; Ser. No. 61/602,878, filed Feb. 24, 2012; Ser. No. 61/602,876, filed Feb. 24, 2012; Ser. No. 61/600,205, filed Feb. 17, 2012; Ser. No. 61/588,833, filed Jan. 20, 2012; Ser. No. 61/583,381, filed Jan. 5, 2012; Ser. No. 61/579,682, filed Dec. 23, 2011; Ser. No. 61/570,017, filed Dec. 13, 2011; Ser. No. 61/568,791, filed Dec. 9, 2011; Ser. No. 61/567,446, filed Dec. 6, 2011; Ser. No. 61/559,970, filed Nov. 15, 2011; Ser. No. 61/552,167, filed Oct. 27, 2011; Ser. No. 61/540,256, filed Sep. 28, 2011; Ser. No. 61/513,745, filed Aug. 1, 2011; and/or Sera No. 61/511,738, filed Jul. 26, 2011, which are all hereby incorporated herein by reference in their entireties. The system may communicate with other communication systems via any suitable means, such as by utilizing aspects of the systems described in PCT Application No. PCT/US10/038,477, filed Jun. 14, 2010, and/or U.S. patent application Ser. No. 13/202,005, filed Aug. 17, 2011 (Attorney Docket MAG04 P-1595), and/or U.S. provisional applications, Ser. No. 61/567,150, filed Dec. 6, 2011; Ser. No. 61/565,713, filed Dec. 1, 2011; and/or Ser. No, 61/537,279, filed Sep. 21, 2011, which are hereby incorporated herein by reference in their entireties.

In the illustrated embodiment, the imaging sensor 14 is disposed at an interior rearview mirror assembly 26 of the vehicle 10, with the imaging array portions 22, 24 having forward fields of view towards and/or through the vehicle windshield 27. However, the imaging sensor of the vision system of the present invention may be disposed elsewhere in the vehicle and may have sideward and/or rearward fields of view, while remaining within the spirit and scope of the present invention. For example, the imaging sensor may be disposed at the rear of the vehicle, with one lens and imaging array portion functioning to capture images or image data of close-up objects, such as for a backup assist and/or trailer hookup assist system, while the other lens and imaging array portion function to capture images or image data of further away or more distant objects, such as for a parking assist system or object detection system or the like.

The imaging device and control and image processor and any associated illumination source, if applicable, may comprise any suitable components, and may utilize aspects of the cameras and vision systems described in U.S. Pat. Nos. 5,550,677; 5,877,897; 6,498,620; 5,670,935; 5,796,094; 6,396,397; 6,806,452; 6,690,268; 7,005,974; 7,123,168; 7,004,606; 6,946,978; 7,038,577; 6,353,392; 6,320,176; 6,313,454; and 6,824,281, and/or International Publication No. WO 2010/099416, published Sep. 2, 2010, and/or PCT Application No. PCT/US10/47256, filed Aug. 31, 2010, and/or U.S. patent application Ser. No. 12/508,840, filed Jul. 24, 2009, and published Jan. 28, 2010 as U.S. Pat. Publication No. US 2010-0020170, which are all hereby incorporated herein by reference in their entireties. The camera or cameras may comprise any suitable cameras or imaging sensors or camera modules, and may utilize aspects of the cameras or sensors described in U.S. patent application Ser. No. 12/091,359, filed Apr. 24, 2008 and published Oct. 1, 2009 as U.S. Publication No. US-2009-0244361; and/or Ser. No. 13/260,400, filed Sep. 26, 2011 (Attorney Docket MAG04 P-1757), and/or U.S. Pat. Nos. 7,965,336 and/or 7,480,149, which are hereby incorporated herein by reference in their entireties. The imaging array sensor may comprise any suitable sensor, and may utilize various imaging sensors or imaging array sensors or cameras or the like, such as a CMOS imaging array sensor, a CCD sensor or other sensors or the like, such as the types described in U.S. Pat. Nos. 5,550,677; 5,670,935; 5,760,962; 5,715,093; 5,877,897; 6,922,292; 6,757,109; 6,717,610; 6,590,719; 6,201,642; 6,498,620; 5,796,094; 6,097,023; 6,320,176; 6,559,435; 6,831,261; 6,806,452; 6,396,397; 6,822,563; 6,946,978; 7,339,149; 7,038,577; 7,004,606; 7,965,336; and/or 7,720,580, and/or PCT Application No. PCT/US2008/076022, filed Sep. 11, 2008 and published Mar. 19, 2009 as International Publication No. WO/2009/036176, and/or PCT Application No. PCT/US2008/078700, filed Oct. 3, 2008 and published Apr. 9, 2009 as International Publication No. WO/2009/046268, which are all hereby incorporated herein by reference in their entireties.

The camera module and circuit chip or board and imaging sensor may be implemented and operated in connection with various vehicular vision-based systems, and/or may be operable utilizing the principles of such other vehicular systems, such as a vehicle headlamp control system, such as the type disclosed in U.S. Pat. Nos. 5,796,094; 6,097,023; 6,320,176; 6,550,435; 6,831,261; 7,004,606; 7,339,149; and/or 7,526,103, which are all hereby incorporated herein by reference in their entireties, a rain sensor, such as the types disclosed in commonly assigned U.S. Pat. Nos. 6,353,392; 6,313,454; 6,320,176; and/or 7,480,149, which are hereby incorporated herein by reference in their entireties, a vehicle vision system, such as a forwardly, sidewardly or rearwardly directed vehicle vision system utilizing principles disclosed in U.S. Pat. Nos. 5,550,677; 5,670,935; 5,760,962; 5,877,897; 5,949,331; 6,222,447; 6,302,545; 6,396,397; 6,498,620; 6,523,964; 6,611,202; 6,201,642; 6,690,268; 6,717,610; 6,757,109; 6,802,617; 6,806,452; 6,822,563; 6,891,563; 6,946,978; and/or 7,859,565, which are all hereby incorporated herein by reference in their entireties, a trailer hitching aid or tow check system, such as the type disclosed in U.S. Pat. No. 7,005,974, which is hereby incorporated herein by reference in its entirety, a reverse or sideward imaging system, such as for a lane change assistance system or lane departure warning system or for a blind spot or object detection system, such as imaging or detection systems of the types disclosed in U.S. Pat. Nos. 7,720,580; 7,038,577; 5,929,786 and/or 5,786,772, and/or U.S. patent application Ser. No. 11/230,980, filed Sep. 30, 2005, now U.S. Pat. No. 7,881,496, and/or U.S. provisional applications, Ser. No, 60/628,709, filed Nov. 17, 2004; Ser. No, 60/614,644, filed Sep. 30, 2004; Ser, No. 60/618,686, filed Oct. 14, 2004; Ser. No. 60/638,687, filed Dec. 23, 2004, which are hereby incorporated herein by reference in their entireties, a video device for internal cabin surveillance and/or video telephone function, such as disclosed in U.S. Pat. Nos. 5,760,962; 5,877,897; 6,690,268; and/or 7,370,983, and/or U.S. patent application Ser. No. 10/538,724, filed Jun. 13, 2005 and published Mar. 9, 2006 as U.S. Publication No. US-2006-0050018, which are hereby incorporated herein by reference in their entireties, a traffic sign recognition system, a system for determining a distance to a leading or trailing vehicle or object, such as a system utilizing the principles disclosed in U.S. Pat. Nos. 6,396,397 and/or 7,123,168, which are hereby incorporated herein by reference in their entireties, and/or the like.

Optionally, the circuit board or chip may include circuitry for the imaging array sensor and or other electronic accessories or features, such as by utilizing compass-on-a-chip or EC driver-on-a-chip technology and aspects such as described in U.S. Pat. No. 7,255,451 and/or U.S. Pat. No. 7,480,149; and/or U.S. patent application Ser. No. 11/226,628, filed Sep. 14, 2005 and published Mar. 23, 2006 as U.S. Publication No. US-2006-0061008, and/or Ser. No. 12/578,732, filed Oct., 14, 2009 (Attorney Docket DON01 P-1564), which are hereby incorporated herein by reference in their entireties.

Optionally, the vision system may include a display, such as a video display for displaying images captured by one or both of the portions of the imaging array of the imaging sensor for viewing by the driver of the vehicle while the driver is normally operating the vehicle. Optionally, for example, the vision system may include a video display device 28 disposed at or in the interior rearview mirror assembly 26 of the vehicle 10 (such as shown in FIG. 1), such as by utilizing aspects of the video mirror display systems described in U.S. Pat. No. 6,690,268 and/or U.S. patent application Ser. No. 13/333,337, filed Dec. 21, 2011 (Attorney Docket DON01 P-1797), which are hereby incorporated herein by reference in their entireties. The video mirror display may comprise any suitable devices and systems and optionally may utilize aspects of the compass display systems described in U.S. Pat. Nos. 7,370,983; 7,329,013; 7,308,341; 7,289,037; 7,249,860; 7,004,593; 4,546,551; 5,699,044; 4,953,305; 5,576,687; 5,632,092; 5,677,851; 5,708,410; 5,737,226; 5,802,727; 5,878,370; 6,087,953; 6,173,508; 6,222,460; 6,513,252; and/or 6,642,851, and/or European patent application, published Oct. 11, 2000 under Publication No. EP 0 1043566, and/or U.S. patent application Ser. No. 11/226,628, filed Sep. 14, 2005 and published Mar. 23, 2006 as U.S. Publication No. US-2006-0061008, which are all hereby incorporated herein by reference in their entireties. Optionally, the video mirror display screen or device may be operable to display images captured by a rearward viewing camera of the vehicle during a reversing maneuver of the vehicle (such as responsive to the vehicle gear actuator being placed in a reverse gear position or the like) to assist the driver in backing up the vehicle, and optionally may be operable to display the compass heading or directional heading character or icon when the vehicle is not undertaking a reversing maneuver, such as when the vehicle is being driven in a forward direction along a road (such as by utilizing aspects of the display system described in PCT Application No. PCT/US2011/056295, filed Oct. 14, 2011 and published on Apr. 19, 2012 as International Publication No. WO 2012/051500, which is hereby incorporated herein by reference in its entirety). Optionally, the vision system (utilizing a forward and/or rearward facing camera and other cameras disposed at the vehicle with exterior fields of view) and/or the camera or cameras as part of a vehicle vision system comprising or utilizing a plurality of cameras (such as utilizing a rearward facing camera and sidewardly facing cameras and a forwardly facing camera disposed at the vehicle), may provide a display of a top-down view or birds-eye view of the vehicle or a surround view at the vehicle, such as by utilizing aspects of the vision systems described in PCT Application No. PCT/US10/25545, filed Feb. 26, 2010 and published on Sep. 2, 2010 as International Publication No. WO 2010/099416, and/or PCT Application No. PCT/US10/47256, filed Aug. 31, 2010 and published Mar. 10, 2011 as International Publication No. WO 2011/028686, and/or PCT Application No. PCT/US11/62755, filed Dec. 1, 2011 and published on Jun. 7, 2012 as International Publication No. WO 2012-075250, and/or U.S. patent application Ser. No. 13/333,337, filed Dec. 21, 2011 (Attorney Docket DON01 P-1797), and/or U.S. provisional applications, Ser. No. 61/615,410, filed Mar. 26, 2012; Ser. No. 61/588,833, filed Jan. 20, 2012; Ser. No. 61/570,017, filed Dec. 13, 2011; Ser. No. 61/568,791, filed Dec. 9, 2011; Ser. No. 61/559,970, filed Nov. 15, 2011; Ser. No. 61/540,256, filed Sep. 28, 2011, which are hereby incorporated herein by reference in their entireties.

Optionally, the video mirror display may be disposed rearward of and behind the reflective element assembly and may comprise a display such as the types disclosed in U.S. Pat. Nos. 5,530,240; 6,329,925; 7,626,749; 7,581,859; 7,338,177; 7,274,501; 7,255,451; 7,195,381; 7,184,190; 5,668,663; 7,855,755; 5,724,187 and/or 6,690,268, and/or in U.S. patent application Ser. No. 11/226,628, filed Sep., 14, 2005 and published Mar. 23, 2006 as U.S. Publication No. US-2006-0061008; and/or Ser. No. 10/538,724, filed Jun. 13, 2005 and published Mar. 9, 2006 as U.S. Publication No. US-2006-0050018, which are all hereby incorporated herein by reference in their entireties. The display is viewable through the reflective element when the display is activated to display information. The display element may be any type of display element, such as a vacuum fluorescent (VF) display element, a light emitting diode (LED) display element, such as an organic light emitting diode (OLED) or an inorganic light emitting diode, an electroluminescent (EL) display element, a liquid crystal display (LCD) element, a video screen display element or backlit thin film transistor (TFT) display element or the like, and may be operable to display various information (as discrete characters, icons or the like, or in a multi-pixel manner) to the driver of the vehicle, such as passenger side inflatable restraint (PSIR) information, tire pressure status, and/or the like. The mirror assembly and/or display may utilize aspects described in U.S. Pat. Nos. 7,184,190; 7,255,451; 7,446,924 and/or 7,338,177, which are all hereby incorporated herein by reference in their entireties. The thicknesses and materials of the coatings on the substrates of the reflective element may be selected to provide a desired color or tint to the mirror reflective element, such as a blue colored reflector, such as is known in the art and such as described in U.S. Pat. Nos. 5,910,854; 6,420,036; and/or 7,274,501, which are hereby incorporated herein by reference in their entireties.

Optionally, the display or displays and any associated user inputs may be associated with various accessories or systems, such as, for example, a tire pressure monitoring system or a passenger air bag status or a garage door opening system or a telematics system or any other accessory or system of the mirror assembly or of the vehicle or of an accessory module or console of the vehicle, such as an accessory module or console of the types described in U.S. Pat. Nos. 7,289,037; 6,877,888; 6,824,281; 6,690,268; 6,672,744; 6,386,742; and 6,124,886, and/or U.S. patent application Ser. No. 10/538,724, filed Jun. 13, 2005 and published Mar. 9, 2006 as U.S. Publication No. US-2006-0050018, which are hereby incorporated herein by reference in their entireties.

The display or displays may comprise a video display and may utilize aspects of the video display devices or modules described in U.S. Pat. Nos. 6,690,268; 7,184,190; 7,274,501; 7,370,983; and/or 7,446,650, and/or U.S. patent application Ser. No. 12/091,525, filed Apr., 25, 2008, now U.S. Pat. No. 7,855,755; and/or Ser. No. 10/538,724, filed Jun. 13, 2005 and published Mar. 9, 2006 as U.S. Publication No. US-2006-0050018, which are all hereby incorporated herein by reference in their entireties. The video display may be operable to display images captured by one or more imaging sensors or cameras at the vehicle.

Changes and modifications to the specifically described embodiments may be carried out without departing from the principles of the present invention, which is intended to be limited only by the scope of the appended claims as interpreted according to the principles of patent law.

1. An imaging system for a vehicle, said imaging system comprising:
an imaging sensor disposed at the vehicle, wherein said imaging sensor comprises an imaging array of photosensing pixels;
a first optical element disposed at a first portion of said imaging array, wherein said first optical element comprises a first focal length;
a second optical element disposed at a second portion of said imaging array, wherein said second optical element comprises a second focal length; and
wherein said first focal length is longer than said second focal length so that said first portion of said imaging array captures focused images of a more remote or distant scene than that of said second portion of said imaging array.

2. The imaging system of claim 1, wherein said imaging sensor is disposed at or in the vehicle so as to have a generally forward field of view in the forward direction of travel of the vehicle.

3. The imaging system of claim 2, wherein said imaging sensor disposed at or in an interior rearview mirror assembly of the vehicle and has a generally forward field of view through the windshield of the vehicle.

4. The imaging system of claim 1, wherein said first portion of said imaging array has a forward field of view through the windshield of the vehicle and said first optical element focuses an image at said first portion of said imaging array that is representative of a scene occurring forwardly of the vehicle at or on the road on which the vehicle is traveling.

5. The imaging system of claim 4, wherein said second optical element focuses an image at said second portion of said imaging array that is representative of at least one surface of the windshield of the vehicle.

6. The imaging system of claim 5, wherein said first portion of said imaging array captures image data for at least one of (a) a headlamp control system of the vehicle, (b) an adaptive cruise control system of the vehicle, (c) a collision avoidance system of the vehicle, (d) a lane departure warning system of the vehicle, (e) a sign detection and recognition system of the vehicle and (f) an object detection system of the vehicle.

7. The imaging system of claim 6, wherein said second portion of said imaging array captures image data for at least one of (a) a rain sensing system of the vehicle, (b) a fog sensing system of the vehicle, (c) a moisture sensing system of the vehicle, (d) a precipitation sensing system of the vehicle, (e) a windshield wiper control system of the vehicle and (f) a climate control system of the vehicle.

8. The imaging system of claim 4, wherein said second portion of said imaging array has a forward field of view through the windshield of the vehicle and wherein said second optical element focuses an image at said second portion of said imaging array that is representative of a scene occurring forwardly of the vehicle and closer to the vehicle than the scene imaged by said first portion of said imaging array.

9. The imaging system of claim 8, wherein said first optical element comprises a higher resolution optical element than said second optical element.

10. The imaging system of claim 1, further comprising a display screen disposed in an interior rearview mirror assembly of the vehicle.

11. The imaging system of claim 10, wherein said display screen comprises a video display screen operable to display video images captures by said first portion of said imaging array.

12. The imaging system of claim 11, wherein said display screen comprises a video mirror display screen and wherein video information displayed by said display screen is viewable through a transflective mirror reflector of the mirror reflective element of said interior rearview mirror assembly of the vehicle.

13. The imaging system of claim 1, wherein said first and second portions of said imaging array are commonly established on a common semiconductor substrate.

14. A imaging system for a vehicle, said imaging system comprising:
a first imaging array disposed at the vehicle, wherein said first imaging array comprises an array of photosensing pixels;
a second imaging array disposed at the vehicle, wherein said second imaging array comprises an array of photosensing pixels;
a first optical element disposed at sad first imaging array, wherein said first optical element comprises a first focal length;
a second optical element disposed at said second imaging array, wherein said second optical element comprises a second focal length;
wherein said first focal length is longer than said second focal length so that said first imaging array captures focused images of a more remote or distant scene than that of said second imaging array; and
wherein said first and second imaging arrays are disposed at or in the vehicle so as to have generally forward fields of view in the forward direction of travel of the vehicle.

15. The imaging system of claim 14, wherein said first and second imaging arrays are spaced apart from one another.

16. The imaging system of claim 14, wherein said first and second imaging arrays are part of a common imaging sensor.

17. The imaging system of claim 14, wherein said first and second imaging arrays are disposed at or in an interior rearview mirror assembly of the vehicle and have generally forward fields of view through the windshield of the vehicle.

18. The imaging system of claim 14, wherein said first imaging array has a forward field of view through the windshield of the vehicle and said first optical element focuses an image at said first imaging array that is representative of a scene occurring forwardly of the vehicle at or on the road on which the vehicle is traveling, and wherein said first imaging array captures image data for at least one of (a) a headlamp control system of the vehicle, (b) an adaptive cruise control system of the vehicle, (c) a collision avoidance system of the vehicle, (d) a lane departure warning system of the vehicle, (e) a sign detection and recognition system of the vehicle and (f) an object detection system of the vehicle.

19. The imaging system of claim 18, wherein said second optical element focuses an image at said second imaging array that is representative of at least one surface of the windshield of the vehicle, and wherein said second imaging array captures image data for at least one of (a) a rain sensing system of the vehicle, (b) a fog sensing system of the vehicle, (c) a moisture sensing system of the vehicle, (d) a precipitation sensing system of the vehicle, (e) a windshield wiper control system of the vehicle and (f) a climate control system of the vehicle.

20. The imaging system of claim 18, wherein said second imaging array has a forward field of view through the windshield of the vehicle and wherein said second optical element focuses an image at said second imaging array that is representative of a scene occurring forwardly of the vehicle and closer to the vehicle than the scene imaged by said first imaging array.

21. The imaging system of claim 20, wherein said first optical element comprises a higher resolution optical element than said second optical element.

22. The imaging system of claim 14, further comprising a display screen disposed in an interior rearview mirror assembly of the vehicle, and wherein said display screen comprises a video display screen operable to display video images captures by said first imaging array.

23. An imaging system for a vehicle, said imaging system comprising:
an imaging sensor disposed at the vehicle, wherein said imaging sensor comprises a CMOS imaging array sensor having an imaging array of photosensing pixels established on a semiconductor substrate;
a first optical element disposed at a first portion of said imaging array, wherein said first optical element comprises a first focal length;
a second optical element disposed at a second portion of said imaging array, wherein said second optical element comprises a second focal length;
wherein said first focal length is longer than said second focal length so that said first portion of said imaging array captures focused images of a more remote or distant scene than that of said second portion of said imaging array;
wherein said first portion of said imaging array captures image data for at least one of (a) a headlamp control system of the vehicle, (b) an adaptive cruise control system of the vehicle, (c) a collision avoidance system of the vehicle, (d) a lane departure warning system of the vehicle, (e) a sign detection and recognition system of the vehicle and (f) an object detection system of the vehicle; and
wherein said second portion of said imaging array captures image data for at least one of (i) a rain sensing system of the vehicle, (ii) a fog sensing system of the vehicle, (iii) a moisture sensing system of the vehicle, (iv) a precipitation sensing system of the vehicle, (v) a windshield wiper control system of the vehicle and (vi) a climate control system of the vehicle.

24. The imaging system of claim 23, wherein said imaging sensor is disposed at or in the vehicle so as to have a generally forward field of view in the forward direction of travel of the vehicle and through the windshield of the vehicle.

25. The imaging system of claim 23, wherein said first portion of said imaging array has a forward field of view through the windshield of the vehicle and said first optical element focuses an image at said first portion of said imaging array that is representative of a scene occurring forwardly of the vehicle at or on the road on which the vehicle is traveling.

26. The imaging system of claim 25, wherein said second optical element focuses an image at said second portion of said imaging array that is representative of at least one surface of the windshield of the vehicle.

27. The imaging system of claim 23, wherein said first optical element comprises a higher resolution optical element than said second optical element.
